(19) United States
(12) Patent Application Publication
(10) Pub. No.: US 2023/0119215 A1
(43) Pub. Date: Apr. 20, 2023

(54) CURRENT SENSOR

(71) Applicant: Continental Automotive Technologies GmbH, Hannover (DE)

(72) Inventors: Michael Irsigler, Frankfurt am Main (DE); Matthias Böhm, Frankfurt am Main (DE); Dirk Grobe, Frankfurt am Main (DE); Sudarshan Rao, Frankfurt am Main (DE)

(73) Assignee: Continental Automotive Technologies GmbH, Hannover (DE)

(21) Appl. No.: 17/905,370

(22) PCT Filed: Feb. 18, 2021
(86) PCT No.: PCT/DE2021/200018

§ 371 Date: Aug. 31, 2022

(30) Foreign Application Priority Data
Mar. 3, 2020 (DE) 10 2020 202 694.7

(51) Int. Cl. H01M 10/48; H01M 10/42; G01R 15/20

(52) U.S. Cl. CPC H01M 10/48; H01M 10/425; G01R 15/202; G01R 15/207

(57) ABSTRACT

A battery sensor for detecting a current flowing through an electrical conductor, wherein the battery sensor has at least two mutually independent measuring devices for detecting the current flowing through the electrical conductor. The measuring devices are structurally and/or electrically completely isolated from one another.

### CROSS-REFERENCE TO RELATED APPLICATIONS

The present application is a National Stage Application under 35 U.S.C. § 371 of International Patent Application No. PCT/DE2021/200018 filed on Feb. 18, 2021, and claims priority from German Patent Application No. 10 2020 202 694.7 filed on Mar. 3, 2020, in the German Patent and Trademark Office, the disclosures of which are herein incorporated by reference in their entireties.

### BACKGROUND

### 1. Field

The development relates to a current sensor for measuring current in a vehicle using two independent measuring principles.

### 2. Description of Related Art

Batteries with high voltages are used in vehicles, in particular in electric vehicles or hybrid vehicles. When the vehicle is in operation, the battery currents have to be constantly recorded in order to be able to make precise statements about the state of charge of the vehicle battery.

In order to guarantee the reliability required in the automotive sector and to ensure the required accuracy of the current measurement, a redundant current measurement has to be provided, in particular using two mutually independent sensors and/or measuring principles. Such a sensor is described for example in EP2732295A1.

### SUMMARY

Aspects of embodiments of the present application relate to a sensor described above for increasing measurement accuracy and the reliability.

In order to achieve the object, provision is made of a battery sensor for detecting a current flowing through an electrical conductor, wherein the battery sensor has at least two mutually independent measuring devices for detecting the current flowing through the electrical conductor. The measuring devices are structurally and/or electrically completely isolated from one another. The complete isolation of the measuring devices reliably ensures that they do not influence one other.

For example, each measuring device is arranged on a separate printed circuit board. This means that the measuring devices do not use any common components, with the result that influences on one component do not affect the respective other measuring device. In particular, printed circuit boards with a different structure can also be used so that structural disadvantages of a specific printed circuit board can occur only in one of the two measuring devices. In particular, the printed circuit boards can be manufactured separately so that errors in production cannot affect both measuring devices.

In order to make the measuring devices completely independent of one another, a separate power supply is preferably provided for each measuring device. Errors in one of the power supplies therefore do not affect the respective other measuring device.

Furthermore, each measuring device preferably has a separate signal input and/or signal output. This means there is no joint signal processing or evaluation within the battery sensor.

In particular, the measuring devices are electrically isolated from one another in order to reliably exclude mutual influencing. For example, the measuring devices are galvanically isolated from one another or galvanically decoupled.

At least one measuring device can function according to a magnetic measuring principle, wherein this measuring device has in particular a Hall sensor. However, it is also possible to use other magnetic measuring principles that detect changes in the magnetic field due to the current flowing through the conductor.

At least one measuring device can have at least one measuring resistor and a voltage detection device for detecting the voltage drop across the measuring resistor. The current flowing via the measuring resistor can be calculated from the measured voltage difference and the known electrical resistance of the measuring resistor by way of Ohms law.

This measuring device is preferably in contact with the electrical conductor upstream and downstream of the measuring resistor for the purpose of voltage detection. In order to prevent a voltage flashover within this measuring device from the electrical conductor to the signal output or the signal input and/or the power supply, apparatuses for electrically isolating the measuring device from the signal inputs or signal outputs and from a connection for the power supply are preferably provided.

For example, these apparatuses have at least one transformer. In particular, such a transformer can be arranged in a space-saving manner within the printed circuit board.

Two measuring devices with the same measuring principle can also be used, for example with a measuring resistor or a magnetic measuring principle. It is only necessary to ensure that the measuring devices are completely independent of one another in order to exclude or at least reduce influences by a common interference factor. However, it is possible for both measuring devices to use the same measuring resistor, as long as the detection of the voltage drops and the signal processing are completely independent of one another and a common influence on both measurements by an interference factor is excluded.

### BRIEF DESCRIPTION OF THE DRAWINGS

Further advantages and features are found in the following description in conjunction with the accompanying drawings, in which:

FIG. 1 shows a schematic illustration of a battery sensor;

FIG. 2 shows a second schematic illustration of a battery sensor; and

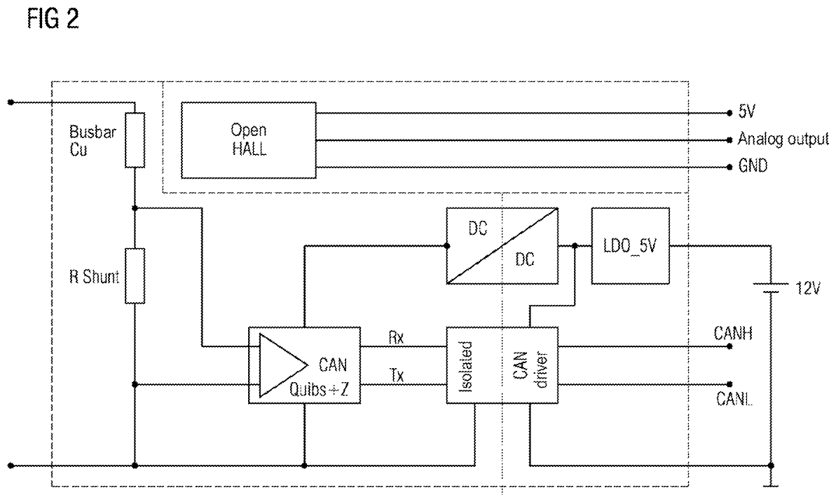

FIG. 3 shows a perspective view of a battery sensor.

### DETAILED DESCRIPTION

The current sensor has an electrical conductor (busbar 800V) which is arranged in the high-voltage circuit and through which the battery current therefore flows. The current sensor is preferably used in vehicles with an electric drive or hybrid drive in order to measure the high currents provided by the vehicle battery or the high currents applied during charging.

A first measuring device is provided on a first section of the electrical conductor, in which a contactless current measurement is performed using a magnetic measuring principle by way of a Hall sensor (contactless ASIC or open loop HALL). The Hall sensor is supplied with power by a low-voltage circuit with 5V (power supply 2), for example by a vehicle battery (12V). Furthermore, the Hall sensor has a signal output (analog out) for outputting the measured values. The Hall sensor itself is not connected to the electrical conductor and therefore has no electrical contact with the high-voltage side (HV). The Hall sensor is therefore located entirely on the low-voltage side (LV).

A second measuring device is provided on a second section, having a measuring resistor (shunt) and a measuring apparatus (shunt Quibz+Z), which makes contact with the electrical conductor in each case upstream and downstream of the measuring resistor. The measuring device can measure the voltage upstream and downstream of the measuring resistor and thus the voltage drop across the measuring resistor. The current flowing via the measuring resistor can be calculated from the voltage difference and the known electrical resistance of the measuring resistor by way of Ohms law.

The second measuring device also has a low-voltage power connection with 5 V or 12 V (power supply 1) and a signal output (CAN out) for outputting the measured values.

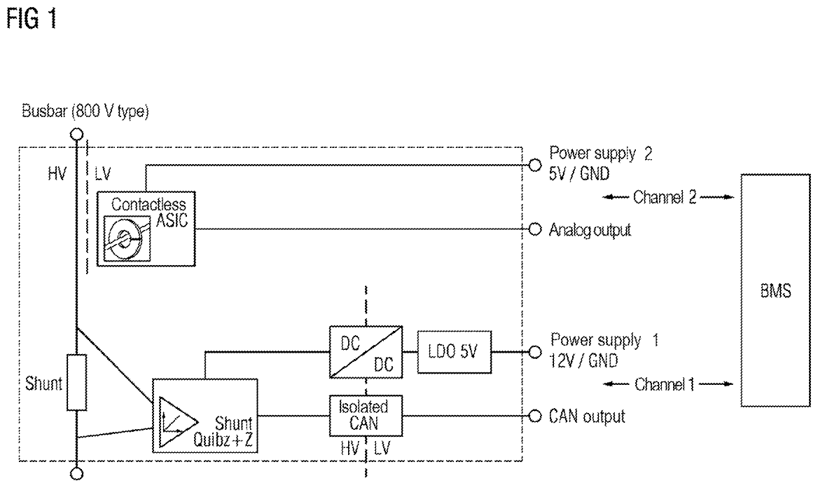

As can be seen in particular in FIG. 1, the second measuring device is connected to the high-voltage circuit via the connections upstream and downstream of the measuring resistor. The isolation between the high-voltage side and the low-voltage side takes place here in the power supply (DC/DC) or in the correspondingly isolated signal output (isolated CAN driver). On the printed circuit board of the second measuring device, for example, the power supply and the signal output are isolated via a transformer that isolates the high-voltage side and the low-voltage side from one another.

Alternatively, other apparatuses of the design measures can be provided, which enable signal transmission or power supply but reliably exclude a voltage.

In order to ensure that the Hall sensor and the shunt measurement are completely independent of each other, they are arranged on different sections of the electrical conductor.

Furthermore, the power supply for both measuring devices is independent of each other, that is to say errors within the power supply only affect the respective measuring device and not both measuring devices.

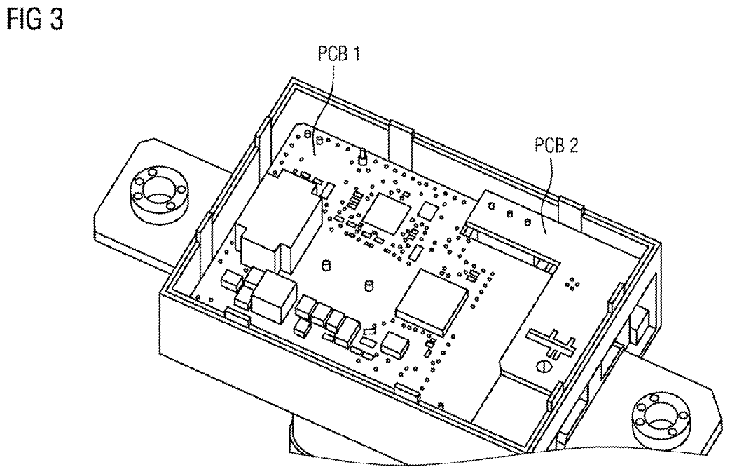

In addition, as can be seen in FIG. 3, separate printed circuit boards (PCB1, PCB2) are provided for both measuring devices. This ensures that the measuring devices are completely isolated from each other and cannot influence each other. In particular, the measuring devices can be spatially positioned relative to one another in any way. In addition, different printed circuit boards can be selected, for example, in order to minimize production influences, for example.

In addition, design measures for isolating the printed circuit boards may be provided in order to exclude any mutual dismissal. For example, a galvanic isolation or decoupling can be provided.

1. A battery sensor for detecting a current flowing through an electrical conductor, the battery sensor comprising:
a first measuring device configured to detect the current flowing through the electrical conductor; and
a second measuring device configured to detect the current flowing through the electrical conductor,
wherein the first measuring device and the second measuring device are structurally and electrically isolated from each other.

2. The battery sensor as claimed in claim 1, further comprising:
a first printed circuit board, wherein the first measuring device is disposed on the first printed circuit board; and
a second printed circuit board, wherein the second measuring device is disposed on the second printed circuit board.

3. The battery sensor as claimed in claim 2, further comprising:
a first power supply electrically coupled to the first measuring device and configured to provide power to the first measuring device; and
a second power supply electrically coupled to the second measuring device and configured to provide power to the second measuring device.

4. The battery sensor as claimed in claim 3, wherein the first measuring device comprises a first signal input and a first signal output and the second measuring device comprises a second signal input and a second signal output.

5. (canceled)

6. The battery sensor as claimed in claim 1, wherein at least one of the first measuring device and the second measuring device functions according to a magnetic measuring principle, and
wherein the at least one of the first measuring device and the second measuring device comprises a Hall sensor.

7. The battery sensor as claimed in claim 1, wherein the first measuring device comprises a measuring resistor and a voltage detection device for detecting a voltage drop across the measuring resistor.

8. The battery sensor as claimed in claim 7, wherein the second measuring device comprises a circuit configured to electrically isolate the second measuring device from signal inputs or signal outputs of the first measuring device.

9. The battery sensor as claimed in claim 8, wherein the circuit comprises at least one transformer.
